(19) United States
(12) Patent Application Publication
(10) Pub. No.: US 2017/0120396 A1
(43) Pub. Date: May 4, 2017

(54) SOLDER PASTE AND SOLDERING FLUX, AND MOUNTED STRUCTURE USING SAME

(71) Applicant: Panasonic Intellectual Property Management Co., Ltd., Osaka (JP)

(72) Inventors: NAOMICHI OHASHI, Hyogo (JP); YUKI YOSHIOKA, Osaka (JP); YASUHIRO SUZUKI, Osaka (JP); HIROHISA HINO, Osaka (JP); MASATO MORI, Hyogo (JP); KAZUHIRO NISHIKAWA, Osaka (JP)

(21) Appl. No.: 15/265,336

(22) Filed: Sep. 14, 2016

(30) Foreign Application Priority Data
Oct. 30, 2015 (JP) 2015-214871

(51) Int. Cl. B23K 35/362; B23K 35/02; B23K 35/26; H01L 21/56; H05K 1/18; H05K 3/34; H01L 23/00; H01L 23/31; B23K 1/00; B23K 35/36

(52) U.S. Cl. CPC B23K 35/362; B23K 1/0016; B23K 35/025; B23K 35/264; B23K 35/3613; B23K 35/3615; B23K 35/3618; B23K 35/3612; H05K 1/181; H05K 3/3457; H05K 3/3436; H05K 3/3494; H05K 3/3489; H01L 24/17; H01L 23/3142; H01L 24/81; H01L 21/563; H05K 2201/10734; H01L 2224/16227; H01L 2224/81815; H01L 2224/81411; H01L 2224/81413; H01L 2924/0665; H01L 2924/20102

(57) ABSTRACT

A solder paste having improved self alignment for soldering is provided. The solder paste includes a solder powder; a composite epoxy resin containing a first epoxy resin that is solid at 25° C., and a second epoxy resin that is liquid at 25° C.; and a curing agent, wherein the first epoxy resin has a softening point that is at least 10° C. lower than the melting point of the solder powder, and is contained in a range of 10 weight parts to 75 weight parts with respect to the total 100 weight parts of the composite epoxy resin.

### TECHNICAL FIELD

This disclosure relates to a solder paste and a soldering flux for electrically connecting various components such as SMT (surface mount technology) components on a circuit board, and to a mounted structure.

### BACKGROUND

Mobile devices such as cell phones and PDAs (Personal Digital Assistants) have never been smaller and more functional. A variety of mounted structures such as BGA (Ball Grid Array), and CSP (Chip Scale Package) are available as amount technology for accommodating such advancements. Mobile devices are prone to mechanical load such as dropping impact. It is therefore important to make the impact resistance of a solder joint reliable in EGA, CSP, and other such mounted structures that do not have a mechanism that relieves impact, such as the leads of a QFP (Quad Flat Package).

To this end, it is known to use an underfill sealant for reinforcement of a solder connection, for example, between a BGA-type semiconductor package and an electronic circuit board. Specifically, a technique is available in which a BGA-type semiconductor package and art electronic circuit board are fixed to each other by charging a reinforcing resin material into the space between the BGA-type semiconductor package and the electronic circuit board after soldering. This relieves the stress due to heat or mechanical impact, and improves the reliability of the impact resistance at the joint. Thermosetting epoxy resins are commonly used as underfill sealants.

However, a drawback of the reinforcement by an underfill sealant is that it requires, for example, cashing the flux residue, or heating after soldering. These add to the manufacturing steps.

As a countermeasure against such a drawback, a solder material is available that does not require washing the flux residue, or heating after soldering, and that improves the reliability of the impact resistance of a solder joint, specifically, a solder paste of a thermosetting resin contained in a flux component, as disclosed in, for example, JP-A-2013-123078.

Concerning the flux component of related art, use of the solder paste for soldering with the thermosetting resin contained therein as in the foregoing related art enables reinforcing the solder joint without requiring washing the flux residue, or heating after soldering.

### SUMMARY

The flux component of related art contains a high-viscosity thermosetting resin in the foregoing configuration. As a rule, a solder melts, and wets and spreads over the substrate and to the electrodes of components, and joins the components as the components return to their intended positions, as commonly known in the art as self alignment. Self alignment corrects a misalignment of components However, self alignment may become less effective because of the high-viscosity thermosetting resin. The solder paste containing a thermosetting resin in a flux component is therefore problematic in terms of poor self alignment in soldering.

FIG. 5 is a cross sectional view of a joint portion in a mounted structure of a semiconductor package mounted with a solder paste of related art. In this mounted structure, because of the high-viscosity thermosetting resin 17, poor self alignment occurs while melting the solder when the solder paste of related art is used as in FIG. 5. The solder thus joins the CSP package 4 with the center of a solder bump 5 out of alignment from the center of the electrode 2 of a substrate 1.

In order to improve the poor self alignment due to the solder paste containing a thermosetting resin in a flux component, it might be possible, as a general approach, to add a plasticizer having a melting point at or below the melting point of the solder, and lower the viscosity of the solder paste at the melting point of the plasticiser. In this case, however, a phenomenon called “bleed out” occurs in which the plastic component spatters around the soldered portion, with the result that the reinforcement effect by the thermosetting resin becomes less effective.

The present disclosure is intended to solve the problems of the related art, and an object of the present disclosure is to provide a solder paste and a soldering flux that exhibit desirable self alignment even when the material contains a thermosetting resin in a flux component, and to provide a mounted structure.

A solder paste according the present disclosure includes:

a solder powder;

a composite epoxy resin containing a first epoxy resin that is solid at 25° C., and a second epoxy resin that is liquid at 25° C.; and

a curing agent,

wherein the first epoxy resin has a softening point that is at least 10° C. lower than the melting point of the solder powder, and is contained in a range of 10 weight parts to 75 weight parts with respect to the total 100 weight parts of the composite epoxy resin.

As set forth above, a solder paste according to the present disclosure includes a composite epoxy resin containing a first epoxy resin that is solid at 25° C. The first epoxy resin has a softening point that is at least 10° C. lower than the melting point of the solder powder. In a mount step, the first epoxy resin becomes less viscous, and liquefies upon being heated at a temperature below the melting point of the solder powder, and above the softening point of the first epoxy resin. This makes the composite epoxy resin less viscous as a whole, and wet and spread over the joint interface between the substrate and the component. The liquefied composite epoxy resin exhibits self alignment. By subsequently heating the solder paste at a temperature above the melting point of the solder powder, self alignment occurs as the solder powder melts. The solder paste according to the present disclosure can thus exhibit self alignment twice, when liquefying the composite epoxy resin and when melting the solder powder. This makes it possible improve self alignment.

### BRIEF DESCRIPTION OF THE DRAWINGS

FIG. 1A is a schematic cross sectional view representing a state in which a solder paste has been supplied to the electrodes of a substrate before a mount step in which a component is mounted on a substrate with a solder paste according to First Embodiment.

FIG. 1B is a schematic cross sectional view representing a state in which a misalignment has occurred in registering the components with the substrate in a mount step in which a component is mounted on a substrate with a solder paste according to First Embodiment.

FIG. 1C is a schematic cross sectional view representing a state in which the heating temperature has exceeded the softening point of the first epoxy resin of the solder paste in a mount step in which a component is mounted on a substrate with a solder paste according to First Embodiment.

FIG. 1D is a schematic cross sectional view representing a state after the heating temperature exceeded the melting point of the solder powder in a mount step in which a component is mounted on a substrate with a solder paste according to First Embodiment.

FIG. 1E is a schematic cross sectional view representing a configuration of a mounted structure according to First Embodiment.

FIG. 2A is a schematic view representing a state immediately after a solder bump is mounted on the solder paste.

FIG. 2B is a schematic view representing a state after the heating in a reflow furnace or the like has raised the temperature of the solder paste above the softening point of the first epoxy resin.

FIG. 2C is a schematic view representing a state after the heating temperature has exceeded the melting point of the solder powder.

FIG. 3 is a schematic cross sectional view representing a cross sectional structure of a joint portion of the mounted structure of a semiconductor package mounted according to First Embodiment.

FIG. 4A is a schematic cross sectional view representing a state in which a soldering flux has been supplied to the electrodes of a substrate before a mount step in which a component is mounted on a substrate with a soldering flux according to Second Embodiment.

FIG. 4B is a schematic cross sectional view representing a state in which a misalignment has occurred in registering the components with the substrate in a mount step in which a component is mounted on a substrate with a soldering flux according to Second Embodiment.

FIG. 4C is a schematic cross sectional view representing a state in which the heating temperature has exceeded the softening point of the first epoxy resin of the soldering flux in a mount step in which a component is mounted on a substrate with a soldering flux according to Second Embodiment.

FIG. 4D is a schematic cross sectional view representing a state after the heating temperature exceeded the melting point of the solder in a mount step in which a component is mounted on a substrate with a soldering flux according to Second Embodiment.

FIG. 4E is a schematic cross sectional view representing a configuration of a mounted structure according to Second Embodiment.

FIG. 5 is a cross sectional view of a cross sectional structure of a joint portion in a mounted structure of a semiconductor package mounted with a solder paste of related art.

### DESCRIPTION OF EMBODIMENTS

A solder paste according a first aspect includes:

a solder powder;

a composite epoxy resin containing a first epoxy resin that is solid at 25° C., and a second epoxy resin that is liquid at 25° C.; and

a curing agent,

wherein the first epoxy resin has a softening point that is at least 10° C. lower than the melting point of the solder powder, and is contained in a range of 10 weight parts to 75 weight parts with respect to the total 100 weight parts of the composite epoxy resin.

In a second aspect, the solder paste according the first aspect may be such that the composite epoxy resin is a mixed epoxy resin that is liquid at 25° C., and in which the first epoxy resin that is solid at 25° C. is dissolved in the second epoxy resin that is liquid at 25° C.

In a third aspect, the solder paste according to the first or second aspect may be such that the first epoxy resin has a viscosity of 2 Pa·s or less at the melting point of the solder powder.

In a fourth aspect, the solder paste according to any one of the first to third aspects maybe such that the solder powder contains Sn and Bi.

A soldering flux according to a fifth aspect solders an electrode of a substrate and an electrode of a component to be mounted on the substrate to each other at least one of which is provided with a solder,

the soldering flux including:

a composite epoxy resin containing a first epoxy resin that is solid at 25° C., and a second epoxy resin that is liquid at 25° C.; and

a curing agent,

wherein the first epoxy resin has a softening point that is at least 10° C. lower than the melting point of the solder provided for at least one of the electrode of the substrate and the electrode of the component, and is contained in a range of 10 weight parts to weight parts with respect to the total 100 weight parts of the composite epoxy resin.

In a sixth aspect, the soldering flux according to the fifth aspect may be such that the composite epoxy resin is a mixed epoxy resin that is liquid at 25° C., and in which the first epoxy resin that is solid at 25° C. is dissolved in tie second epoxy resin that is liquid at 25° C.

In a seventh aspect, the soldering flux according to the fifth or sixth aspect may be such that the first epoxy resin has a viscosity of 2 Pa·s or less at the melting point of the solder provided for at least one of the electrode of the substrate and the electrode of the component.

A mounted structure according to an eighth aspect includes:

a substrate having a plurality of first electrodes;

a component having a second electrode;

a solder that connects between the first electrodes and the second electrode; and

a cured epoxy resin covering at least a part of surroundings of the solder, and occurring upon curing of a composite epoxy resin containing a first epoxy resin that is solid at 25° C., and a second epoxy resin that is liquid at 25° C.,

wherein the first epoxy resin has a softening point that is at least 10° C. lower than the melting point of the solder, and is contained in a range of 10 weight parts to 75 weight parts with respect to the total 100 weight parts of the composite epoxy resin.

Amounted structure producing method according to a ninth aspect is a method for producing a mounted structure that includes: a substrate having a plurality of first electrodes; a component having a second electrode; a solder connecting between the first electrodes and the second electrode; and a cured epoxy resin covering at least a part of surroundings of the solder,

the method including:

providing the solder paste of any one of the foregoing first to fourth aspects for the plurality of first electrodes provided on the substrate, and/or for the second electrode of the component to be mounted on the substrate;

positioning the plurality of first electrodes provided on the substrate, and the second electrode of the component via the solder paste;

heating the solder paste first to a temperature equal to or greater than the softening point of the first epoxy resin, and then to a temperature equal to or greater than the melting point of the solder powder so as to solder the plurality of first electrodes on the substrate and the second electrode of the component to each other with the solder paste separated into the solder connecting between the first electrodes and the second electrode, and a cured epoxy resin covering at least a part of surroundings of the solder, and occurring upon curing of the composite epoxy resin containing the first epoxy resin that is solid at 25° C., and the second epoxy resin that is liquid at 25° C.

Amounted structure producing method according to a tenth aspect is a method for producing a mounted structure that includes: a substrate having a plurality of first electrodes; a component having a second electrode; a solder connecting between the first electrodes and the second electrode; and a cured epoxy resin covering at least a part of surroundings of the solder,

the method including:

providing a solder for the plurality of first electrodes provided on the substrate, and/or for the second electrode of the component to be mounted on the substrate;

providing the soldering flux of any one of the foregoing fifth to eighth aspects on the plurality of first electrodes provided on the substrate, and/or on the second electrode of the component to be mounted on the substrate;

positioning the plurality of first electrodes provided on the substrate, and the second electrode of the component via the solder and the soldering flux; and

heating the solder and the soldering flux first to a temperature equal to or greater than the softening point of the first epoxy resin, and then to a temperature equal to or greater than the melting point of the solder so as to solder the plurality of first electrodes on the substrate and the second electrode of the component to each other with the solder connecting between the first electrodes and the second electrode, and with the soldering flux cured into a cured epoxy resin covering at least a part of surroundings of the solder, and occurring upon curing of the composite epoxy resin containing the first epoxy resin that is solid at 25° C., and the second epoxy resin that is liquid at 25° C.

Embodiments of the solder paste and the soldering flux, and the mounted structure using same according to the present disclosure are described below. In the accompanying drawings, the same components are referred to with the same reference numerals.

### First Embodiment

### Solder Paste

A solder paste according to First Embodiment is configured to include, as essential components, a solder powder; a composite epoxy resin containing a first epoxy resin that is solid at 25° C., and a second epoxy resin that is liquid at 25° C.; and a curing agent for the composite epoxy resin. The first epoxy resin has a softening point that is at least 10° C. lower than the melting point of the solder powder, and is contained in a range of 10 weight parts to 75 weight parts with respect to the total 100 weight parts of the composite epoxy resin. The composite epoxy resin is an epoxy resin mixture that is liquid at 25° C. after heating and mixing. Such a liquid epoxy resin mixture will be referred to as composite epoxy resin. The solder paste may further contain an organic acid for removing oxide films of the solder, the substrate, and the component electrode, and/or a viscosity adjuster, as required.

The solder paste includes a composite epoxy resin containing a first epoxy resin that is solid at 25° C. The first epoxy resin has a softening point that is at least 10° C. lower than the melting point of the solder powder. In a mount step, the first epoxy resin becomes less viscous, arid liquefies upon being heated at a temperature below the melting point of the solder powder, and above the softening point of the first epoxy resin. This makes the composite epoxy resin less viscous as a whole, and wet and spread over the joint interface between the substrate and the component. With the liquefied composite epoxy resin, the component returns to the intended position because of the surface tension difference due to misalignment, even when the component is misaligned from its intended position. This effect is commonly known as self alignment. Self alignment by the liquefied composite epoxy resin differs from self alignment by the melting of the solder powder (described later) in that the solder powder remains unmelted. By subsequently heating the solder paste at a temperature above the melting point of the solder powder, self alignment occurs as the solder powder melts. The solder paste can thus exhibit self alignment twice, when liquefying the composite epoxy resin and when melting the solder powder. This makes it possible improve self alignment.

The constituent members of the solder paste are described below.

### Solder Powder

The solder powder may be of, for example, a simple tin-based alloy or a mixture of such alloys, including, for example, an alloy composition selected from the group consisting of a Sn—Bi-based composition, a Sn—In-based composition, a Sn—Bi—In-based composition, a Sn—Bi—Sb-based composition, a Sn—Ag-based composition, a Sn—Cu-based composition, a Sn—Ag—Cu-based composition, a Sn—Ag—Bi-based composition, a Sn—Cu—Bi-based composition, a Sn—Ag—Cu—Bi-based composition, a Sn—Ag—In-based composition, a Sn—Cu—In-based composition, a Sn—Ag—Cu—In-based composition, and a Sn—Ag—Cu—Bi—In-based composition. Preferably, the solder powder is of a composition containing Sn and Bi, because such compositions have lower melting points.

### First Epoxy Resin

The first epoxy resin is an epoxy resin that is solid at 25° C. The first epoxy resin has a softening point that is at least 10° C. lower than the melting point of the solder powder. Examples of the first epoxy resin include biphenyl-type epoxy resins, naphthalene-type epoxy resins, anthracene-type epoxy resins, triazine-type epoxy resins, dicyclopentadiene-type epoxy resins, triphenylmethane-type epoxy resins, fluorene-type epoxy resins, phenol aralkyl-type epoxy resins, arid novolac-type epoxy resins. As used herein, “epoxy resin that is solid at 25° C.” excludes epoxy resins that are usually liquid at 25° C., and that temporarily become a solid through crystallization, which depends on the storage conditions. In other words, “epoxy resin that is solid at 25° C.” means epoxy resins that become a solid at 25° C. upon being cooled to room temperature after a heat treatment.

### Second Epoxy Resin

The second epoxy resin is an epoxy resin that is liquid at 25° C. Examples of the second epoxy resin include bisphenol A-type epoxy resins, bisphenol F-type epoxy resins, bisphenol S-type epoxy resins, glycidylamine-type resins, alicyclic epoxy resins, and aminopropane-type epoxy resins.

### Composite Epoxy Resin

The composite epoxy resin contains the first epoxy resin that is solid at 25° C., and the second epoxy resin that is liquid at 25° C. The composite epoxy resin is a mixture of the first epoxy resin and the second epoxy resin. Specifically, the composite epoxy resin may be an epoxy resin mixture in which the first epoxy resin that is solid at 25° C. is dissolved in the second epoxy resin that is liquid at 25° C., and that is liquid as a whole at 25° C. Such an epoxy resin mixture is obtained by, for example, heating the first epoxy resin and the second epoxy resin at a temperature above the softening point of the first epoxy resin, and mixing the two.

The first epoxy resin is contained in a range of 10 weight parts to 75 weight parts with respect to the total 100 weight parts of the composite epoxy resin. When the nixed ratio of the first epoxy resin is less than 10 weight parts, the proportion of the first epoxy resin in the whole composite epoxy resin becomes smaller, and the composite epoxy resin fails to sufficiently exhibit the self alignment effect produced by the reduced viscosity and the liquefaction of the first epoxy resin. When the mixed ratio of the first epoxy resin exceeds 75 weight parts, the fluidity after heating and mixing the first epoxy resin with the second epoxy resin suffers, and the mixture cannot be formed into a paste with ease.

### Curing Agent

The curing agent may use, for example, a thiol-based compound, a modified amine-based compound, a multifunctional phenol-based compound, an imidazole-based compound, or an acid anhydride-based compound. These may be used alone, or in a combination of two or more. A preferred compound is selected according to the environment or the use of the solder paste.

### Other Additives

The solder paste may further contain additives for adjusting viscosity, or additives for imparting thixotropy. The additives may be any of various inorganic or organic materials. Examples of such inorganic materials include silica, and alumina. Examples of such organic materials include low-molecular amide compounds, polyester resins, and organic derivatives of castor oil. These may be used either alone or in a combination of two or more. In order to further lower viscosity, it is also possible to add solvents that can dissolve the epoxy resins. In this case, however, there is a risk of lowering the strength of the reinforcing resin, and care must be taken not to lower the strength.

### Solder Paste Mixture Ratio

In a preferred embodiment of the present disclosure, the proportions of the materials mixed in the solder paste are 100 to 700 weight parts for the solder powder, and 5 to 30 weight parts for the curing agent component with respect to the total 100 weight parts of the epoxy resin. However, the present disclosure is not limited to this mixed ratio.

### Mount Step

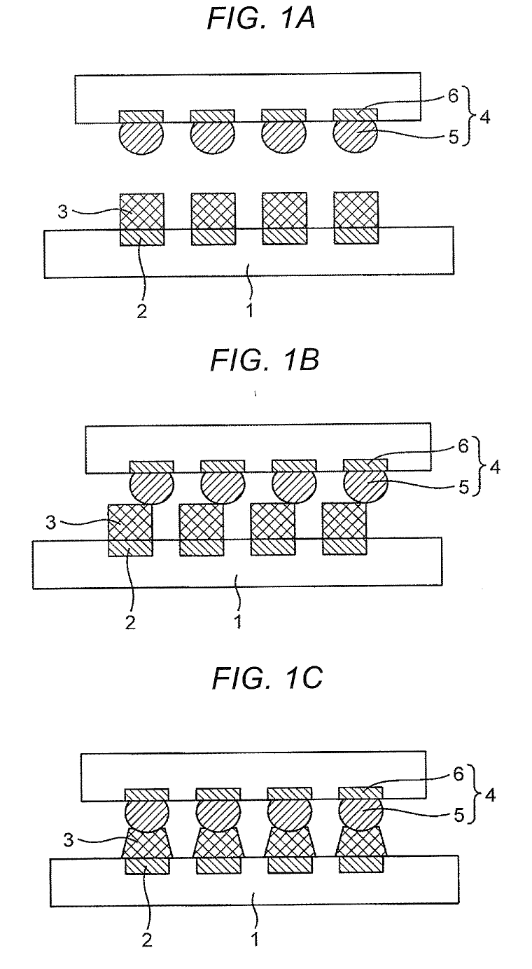

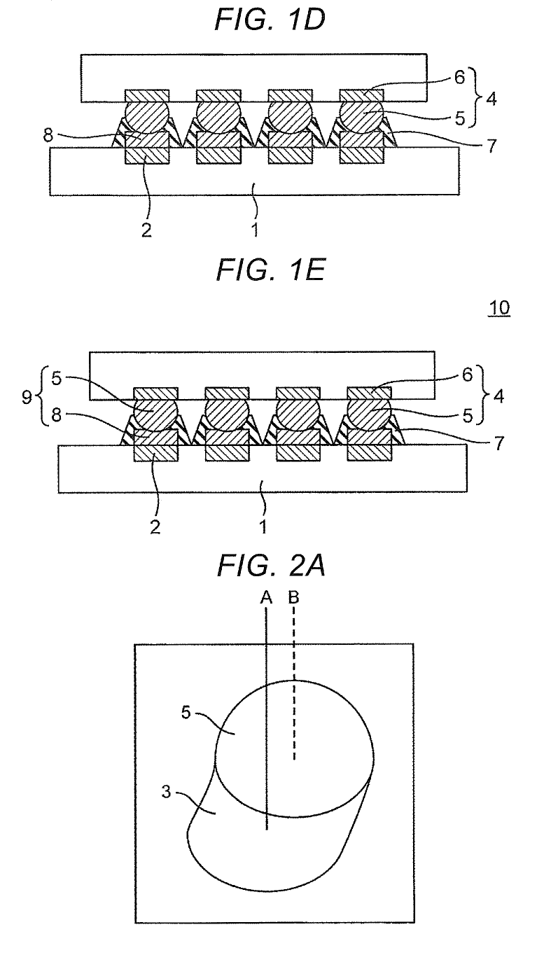

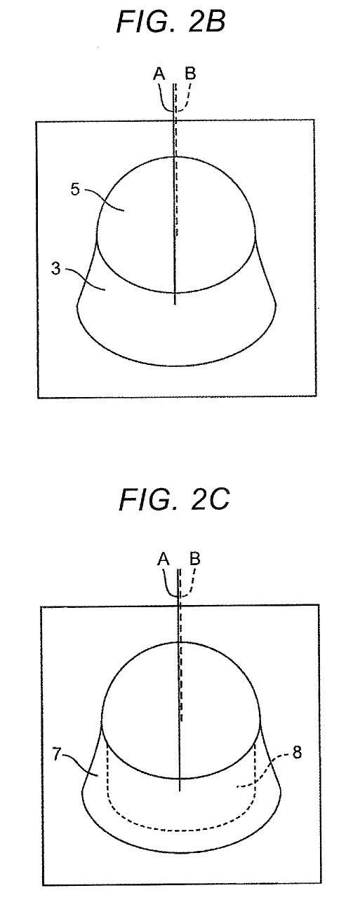

The step of mounting components using the solder paste according to First Embodiment is described below with reference to FIGS. 1A to 1E, and FIGS. 2A to 2C.

(a) First, a solder bump 5 is formed on an electrode 6 of a component 4, and a solder paste is supplied to an electrode 2 of a substrate 1 (FIG. 1A). FIG. 1A is a schematic cross sectional view representing a state in which a solder paste 3 has been supplied to the electrode 2 of the substrate 1 before mounting the component 4. The component 4 is, for example, a CSP package 4. The solder paste 3 is configured to include, as essential components, a solder powder; a composite epoxy resin containing a first epoxy resin that is solid at 25° C., and a second epoxy resin that is liquid at 25° C.; and a curing agent for the composite epoxy resin. The first epoxy resin has a softening point that is at least 10° C. lower than the melting point of the solder powder, and is contained in a range of 10 weight parts to 75 weight parts with respect to the total 100 weight parts of the composite epoxy resin. The solder paste 3 also may be supplied by using methods, for example, such as screen printing, and a transfer method. The solder bump 5 is mounted on the electrode 6 of the CSP package 4. Here, the electrode 6 is provided with the solder bump 5; however, the disclosure is not limited to this, and the solder may be provided by solder plating. The solder paste 3, described herein as being supplied to the electrode 2 of the substrate 1, may be provided on the electrode 6 of the component CSP package 4.

(b) Thereafter, the component and the substrate are registered to each other (FIG. 1B). Here, First Embodiment involves a misalignment occurring in the components, as an example. FIG. 1B is a schematic cross sectional view representing a state in which a misalignment has occurred when registering the components with the substrate. The misalignment of the component 4 is depicted in, for example, the schematic diagram shown in FIG. 2A, which shows how the center line 3 of the solder bump 5 is out of alignment from the center line A of the solder paste 3 on the electrode of the substrate 1.

(c) Thereafter, the solder paste is heated at a temperature above the softening point of the first epoxy resin of the solder paste in a reflow furnace (FIG. 1C). FIG. 1C is a schematic cross sectional view representing a state in which the heating temperature has exceeded the softening point of the first epoxy resin of the solder paste while heating the solder paste in a reflow furnace or the like. In response to the first epoxy resin reducing its viscosity at its softening point, the composite epoxy resin becomes less viscous, liquefies, and wets and spreads over the surfaces of the solder bump 5 and the electrode 2 of the substrate 1. As a result of the composite epoxy resin liquefying by reducing its viscosity, self alignment occurs in which the center line of the solder bump 5 moves closer to the center line of the electrode 2 of the substrate 1.

(d) Thereafter, the solder paste is heated at a temperature above the melting point of the solder powder (FIG. 1D). FIG. 1D is a schematic cross sectional view representing a state after the heating temperature exceeded the melting point of the solder powder. Following the melting of the solder powder, the molten solder wets and spreads to the electrode 2 of the substrate 1, and to the solder bump 5. This produces self alignment in which the center of the solder bump 5 moves closer to the center of the electrode 2 of the substrate 1. As a result, the component CSP package 4 becomes aligned substantially at its intended position, and mounted thereon. While the molten solder powder wets and spreads to the electrodes, a composite epoxy resin 7 becomes separated from the solder powder, and covers the surroundings of a molten solder 8.

(e) This completes a mounted structure of the component CSP package 4 on the substrate 1 (FIG. 1E). FIG. 1E is a schematic cross sectional view representing a configuration of a mounted structure 10 according to First Embodiment. In FIG. 1E, the solder bump 5 and the molten solder 3 are shown as being separated from each other as in FIG. 1D. However, these may occur as a single unit in the form of a solder joint 9.

In the mount step using the solder paste of the present disclosure, self alignment occurs as the first epoxy resin softens and becomes less viscous, and the composite epoxy resin reduces its viscosity and aligns the components, before melting the solder. This, combined with the self alignment occurring after the subsequent melting of the solder powder, enhances the overall self alignment effect.

FIGS. 2A to 2C are diagrams explaining how the component is aligned by the self alignment occurring in the mount step with the solder paste according to First Embodiment as a result of the reduced viscosity of the composite epoxy resin before melting the solder. In FIGS. 2A to 2C, the component is mounted by registering the solder bump 5 provided on the component CSP package to the solder paste 3 on the substrate.

FIG. 2A is a schematic view representing a state immediately after the solder bump 5 is mounted on the solder paste 3. FIG. 2A corresponds to the steps of FIGS. 1A and IB. Here, the center line A of the solder paste 3, and the center line B of the solder bump 5 are intentionally misaligned.

FIG. 2B is a schematic view representing a state after the heating in a reflow furnace or the like has raised the temperature of the solder paste 3 above the softening point of the first epoxy resin. FIG. 2B corresponds to the step of FIG. 1C. As depicted in the figure, self alignment occurred solely by the effect of the reduced viscosity of the composite epoxy resin before melting of the solder took place, bringing the center Line B of the solder bump closer to the center line A of the solder paste, and demonstrating the effect of the present disclosure. In this diagram, the component is aligned with the center line B of the solder bump substantially matching the center line A of the solder paste.

FIG. 2C is a schematic view representing a state after the heating temperature has exceeded the melting point of the solder powder. FIG. 2C corresponds to the step of FIG. 1D. The molten solder powder produces self alignment as it wets and spreads to the substrate electrode 2 and to the solder bump 5, moving the center line B of the solder bump 5 closer to the center line A of the solder paste 3. While the molten solder powder wets and spreads to the electrode, the composite epoxy resin 7 becomes separated from the solder powder, and covers the surroundings of the molten solder 8.

### Mounted Structure

FIG. 1E is a schematic cross sectional view illustrating a configuration of the mounted structure 10 according to First Embodiment.

The mounted structure 10 includes a substrate 1 having a plurality of electrodes 2, a component 4 having an electrode 6, a solder 5 and a solder 8 connecting between the electrodes 2 and the electrode 6 to each other, and a cured epoxy resin 7 covering at least a part of the surroundings of the solder 8, and occurring upon curing of a composite epoxy resin containing a first epoxy resin that is solid at 25° C., and a second epoxy resin that is liquid at 25° C. The first epoxy resin has a softening point that is at least 10° C. lower than the melting point of the solder 8, and is contained in a range of 10 weight parts to 75 weight parts with respect to the total 100 weight parts of the composite epoxy resin.

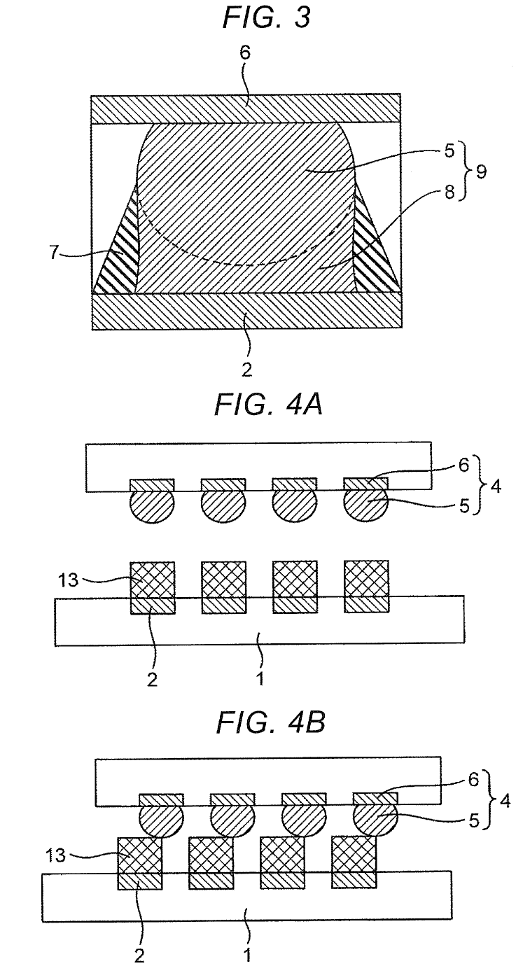

FIG. 3 is a schematic cross sectional view representing a cross sectional structure of a joint portion of the mounted structure of a semiconductor package mounted according to First Embodiment. In this mounted structure, the solder bump 5 and the molten solder 8 are joined to each other in such a manner that the center of the solder bump 5 provided on the electrode 6 of the component CSP package lies substantially on the center of the electrode 2 of the substrate 1. The cured epoxy resin 7 of the composite epoxy resin covers the surroundings of the molten solder 8.

The mounted structure can be obtained by performing the mount step represented in FIGS. 1A to 1E, and FIGS. 2A to 2C. Specifically, the solder paste is used in which a solder powder; a composite epoxy resin containing a first epoxy resin that is solid at 25° C., and a second epoxy resin that is liquid at 25° C.; and a curing agent for the composite epoxy resin are contained as essential components. The first epoxy resin has a softening point that is at least 10° C. lower than the melting point of the solder powder, and is contained in a range of 10 weight parts to 75 weight parts with respect to the total 100 weight parts of the composite epoxy resin.

In the mount step using the solder paste, the solder paste is heated at a temperature below the melting point of the solder powder contained in the solder paste, and above the softening point of the first epoxy resin. Self alignment occurs as the first epoxy resin softens and reduces its viscosity, and the composite epoxy resin becomes less viscous and aligns the component, before melting of the solder takes place. The solder paste is then heated at a temperature above the melting point of the solder powder contained therein. Self alignment occurs as a result of the melting of the solder powder. With the dual self alignment effect, the resulting mounted structure can have improved self alignment.

### Second Embodiment

### Soldering Flux

The soldering flux according to Second Embodiment differs from the solder paste according to First Embodiment in that it does not contain the solder powder. The soldering flux is configured to include a composite epoxy resin, and a curing agent as essential components. The soldering flux nay further contain an organic acid for removing oxide films of the solder, the substrate, and the component electrode, and/or a viscosity adjuster, as required. The soldering flux is used mainly for soldering of components and substrate electrodes provided with solder bumps or a solder plating. However, the applicable areas of the soldering flux are not particularly limited.

### Mount Step

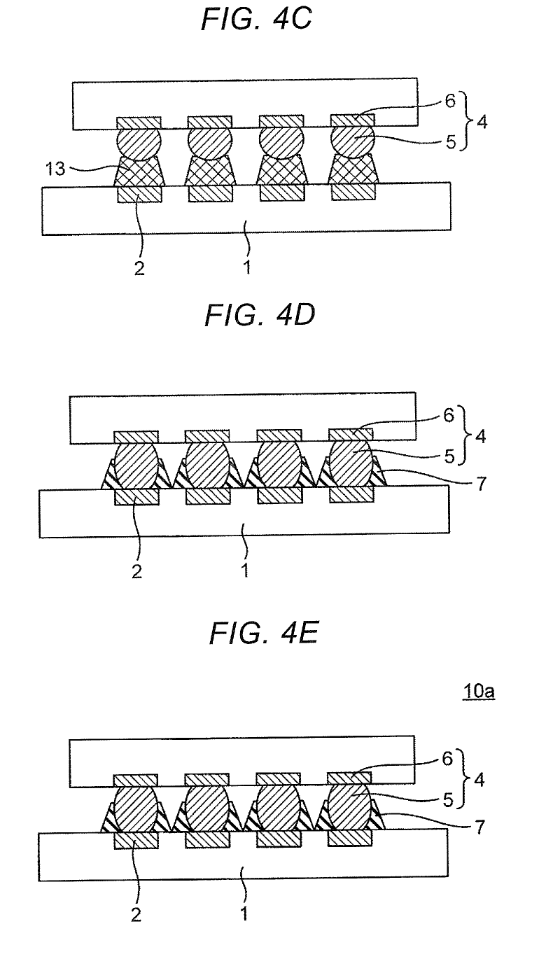

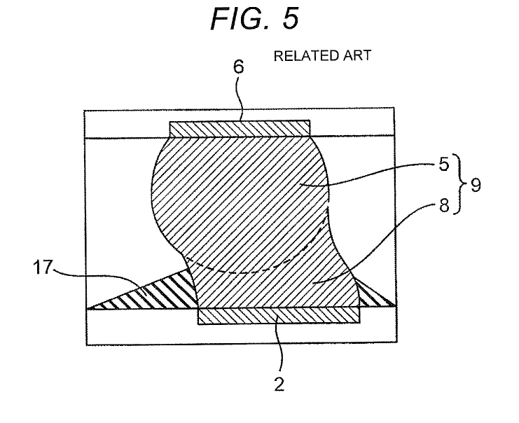

A component mount step using the soldering flux according to Second Embodiment is described below with reference to FIGS. 4A to 4E.

(a) First, a solder bump 5 is formed on an electrode 6 of a component 4, and a soldering flux 13 is supplied to an electrode 2 of a substrate 1 (FIG. 4A). FIG. 4A is a schematic cross sectional view representing a state in which the soldering flux 13 has been supplied to the electrode 2 of the substrate 1 before mounting the component 4.

(b) Thereafter, the component and the substrate are registered to each other (FIG. 4B). Here, Second Embodiment involves a misalignment occurring in the components, as an example. FIG. 4B is a schematic cross sectional view representing a state in which a misalignment has occurred in registering the components with the substrate.

(c) Thereafter, the soldering flux is heated at a temperature above the softening point of the first epoxy resin of the soldering flux in a reflow furnace (FIG. 4C). FIG. 4C is a schematic cross sectional view representing a state in which the heating temperature has exceeded the softening point of the first epoxy resin while heating the soldering flux in a reflow furnace or the like. In response to the first epoxy resin reducing its viscosity at its softening point, the composite epoxy resin becomes less viscous, liquefies, and wets and spreads over the surfaces of the solder bump 5 and the electrode 2 of the substrate 1. As a result of the composite epoxy resin liquefying by reducing its viscosity, self alignment occurs in which the center line of the solder bump 5 moves closer to the center line of the electrode 2 of the substrate 1.

(d) Thereafter, the soldering flux is heated at a temperature above the melting point of the solder bump (FIG. 4D). FIG. 4D is a schematic cross sectional view representing a state after the heating temperature exceeded the melting point of the solder bump. Following the melting of the solder bump, the molten solder 5 wets and spreads to the electrode 2 of the substrate 1. This produces self alignment in which the center of the solder bump 5 moves closer to the center of the electrode 2 of the substrate 1. As a result, the component CSP package 4 becomes aligned substantially at its intended position, and mounted thereon. Here, the composite epoxy resin 7 covers the surroundings of the molten solder 5.

(e) This completes a mounted structure 10a of the component CSP package 4 on the substrate 1 (FIG. 4E). FIG. 4E is a schematic cross sectional view representing a configuration of the mounted structure 10a according to Second Embodiment. The mounted structure 10a includes a substrate 1 having a plurality of electrodes 2, a component 4 having an electrode 6, a solder bump 5 connecting between the electrodes 2 and the electrode 5 to each other, and a cured epoxy resin 7 covering at least a part of the surroundings of the solder bump 5.

With the soldering flux of the present disclosure, self alignment occurs as the first epoxy resin softens and reduces its viscosity, and the composite epoxy resin becomes less viscous and aligns the components, before melting of the solder takes place. This improves the self alignment.

### Mounted Structure

FIG. 4E is a schematic cross sectional view illustrating a configuration of the mounted structure 10a according to Second Embodiment.

The mounted structure 10a includes a substrate 1 having a plurality of first electrodes 2, a component 4 having a second electrode 6, a solder bump S connecting the first electrodes 2 and the second electrode 6 to each other, and a cured epoxy resin 7 covering at least a part of the surroundings of the solder 5, and occurring upon curing of the composite epoxy resin containing a first epoxy resin that is solid at 25° C., and a second epoxy resin that is liquid at 25° C. The first epoxy resin has a softening point that is at least 10° C. lower than the melting point of the solder 5, and is contained in a range of 10 weight parts to 75 weight parts with respect to the total 100 weight parts of the composite epoxy resin.

### EXAMPLES

### Example 1

In this Example, production of a solder paste is described, followed by the mount step of mounting a CSP package on a substrate using the solder paste.

### Solder Paste

Spherical particles of the composition 25Sn-55Bi-20In were used as the solder powder. The solder powder had an average particle size (number average particle size) of 25 μm, and a melting point of 96° C.

A naphthalene-type epoxy resin HP-4770 (manufactured by DIC) was used as a first epoxy resin component. A bisphenol F-type epoxy resin 806 (manufactured by Mitsubishi Chemical Corporation) was used as a second epoxy resin component. The Shikoku Chemicals Corporation product 2P4MHZ was used as an imidazole-based curing agent. Because the solder powder has a melting point of 96° C., the first epoxy resin needs to have a softening point of 86° C. or less.

Glutaric acid was used as an organic acid for removing an oxide film of the solder powder.

A castor oil-based additive THIXCIN R (manufactured by Elementis Japan) was used as a viscosity adjuster.

### Solder Paste Producing Process

a) For the production of the solder paste according to Example 1, a soldering flux was produced, and the solder powder was added to the soldering flux. The mixture was then kneaded to obtain the solder paste. Here, the amount of the flux component added is defined as an amount with respect to 100 weight parts of the solder powder.

b) 20 weight parts of the naphthalene-type epoxy resin, and 30 weight parts of the bisphenol F-type epoxy resin were heated at 150° C. while being mixed, and cooled to room temperature to obtain a liquid epoxy resin as a homogenous mixture of the naphthalene-type epoxy resin and the bisphenol F-type epoxy resin. To the mixture was then added 1 weight part of a thixotropy imparting agent. The mixture was heated and stirred at 150° C. to dissolve the thixotropy imparting agent, and allowed to cool to room temperature. After adding 5 weight parts of the imidazole-based curing agent, and 5 weight parts of glutaric acid, the mixture was kneaded for 10 min with a vacuum planetary mixer to obtain a soldering flux.

c) 100 weight parts of the solder powder was then added to the soldering flux, and the mixture was kneaded for 20 min with a vacuum planetary mixer to obtain the solder paste.

### Mount Step

The following describes the mount step for mounting a chip resistor on a substrate using the solder paste produced in the manner described above.

(1) The solder paste was printed on circuit board electrodes having a diameter φ of 0.28 mm through a metal mask having an aperture size φ of 0.28 mm, and a thickness of 0.03 mm. A BGA-type CSP package (0.5-mm pitch, and 11 mm×11 mm in size) was then mounted on the circuit board, and passed through a 150° C. reflow furnace for 6 min to solder the BGA-type CSP package to the circuit board.

(2) This created a state in which the solder particles had melted, and fused to form a solder joint between the metal clump, the solder bumps of the CSP package, and the substrate electrodes, and in which the epoxy resin layer had surrounded the solder joint.

### Evaluation Methods

In the mount step using the solder paste, the self alignment of the components was evaluated using the following procedures.

The BGA-type CSP package was mounted at positions that were at least 0.15 mm offset from the intended positions in X or Y direction. After being heated in a reflow furnace at 150° C.×6 min, self alignment was evaluated according to the following criteria.

Success: A misalignment was less than 0.05 mm (the component moved back closer to the intended position by 0.1 mm or more)

Acceptable: A misalignment was 0.05 mm or more and less than 0.10 mm (the component moved back closer to the intended position by 0.05 mm or more and less than 0.1 mm)

Fail: A misalignment was 0.10 mm or more (the component moved back closer to the intended position by less than 0.05 mm)

### Examples 2 to 10, Comparative Examples 1 to 5, and Conventional Example

Solder pastes of Examples 2 to 10, Comparative Examples 1 to 5, and Conventional Example were produced in the same manner described in Example 1. After the mount step using each solder paste, the self alignment of components was evaluated in the manner described above. Table 1 summarizes the type, the content, and the softening point of the first epoxy resin component that is solid at 25° C. used in Examples and Comparative Examples, the viscosity of the first epoxy resin at 96° C., which is the melting point of the solder powder of the composition 25Sn-55Bi-20In, and the results of self alignment evaluation. A bisphenol F-type epoxy resin was used as the second epoxy resin that is liquid at 25° C., as in Example 1. In Conventional Example, the solder paste did not contain the first epoxy resin that is solid at 25° C., and the same bisphenol F-type resin used in Example 1 was used alone as the second epoxy resin. The other components, including the curing agent, the organic acid, and the viscosity adjuster are the same as in Example 1.

TABLE 1

| | First epoxy resin (solid at 25° C.) | | | | |
|---|---|---|---|---|---|
| | | Mixed ratio with | | | |
| | | respect to total 100 | | | |
| | | weight parts of | | | Results of self |
| | | composite epoxy | Softening | Viscosity at | alignment |
| | Type | resin (weight parts) | point (° C.) | 96° C. (Pa · s) | evaluation |
| Ex. 1 | Naphthalene-type | 40 | 72 | 0.7 | Success |
| Ex. 2 | Naphthalene-type | 75 | 72 | 0.7 | Success |
| Ex. 3 | Naphthalene-type | 20 | 72 | 0.7 | Success |
| Ex. 4 | Naphthalene-type | 10 | 72 | 0.7 | Acceptable |
| Ex. 5 | Dicyclopentadiene-type | 10 | 60 | 0.1 | Success |
| Ex. 6 | Dicyclopentadiene-type | 40 | 60 | 0.1 | Success |
| Ex. 7 | Dicyclopentadiene-type | 75 | 60 | 0.1 | Success |
| Ex. 8 | Dicyclopentadiene-type | 40 | 82 | 1.5 | Acceptable |
| Ex. 9 | Dicyclopentadiene-type | 75 | 82 | 1.5 | Success |
| Ex. 10 | Triphenylmethane-type | 40 | 65 | 0.2 | Success |
| Com. Ex. 1 | Naphthalene-type | 5 | 72 | 0.7 | Fail |
| Com. Ex. 2 | Dicyclopentadiene-type | 5 | 60 | 0.1 | Fail |
| Com. Ex. 3 | Naphthalene-type | 40 | 95 | Unmeasurable | Fail |
| Com. Ex. 4 | Dicyclopentadiene-type | 40 | 93 | Unmeasurable | Fail |
| Com. Ex. 5 | Cresol novolac-type | 40 | 70 | 2.5 | Fail |
| Conventional | — | 0 | — | — | Fail |
| Example | | | | | |

The following discusses the evaluation results for Examples and Comparative Examples.

A comparison was made between Examples 1 to 4 and Comparative Example 1, and between Examples 5 to 7 and Comparative Example 2. It was found that self alignment was in the acceptable range in materials in which the first epoxy resin that is solid at 25° C. was mixed in 10 to 75 weight parts with respect to 100 weight parts of the composite epoxy resin. On the other hand, self alignment was outside of the acceptable range when the first epoxy resin was mixed in 5 weight parts. Self alignment was outside of the acceptable range also in Conventional Example, which did not contain the first epoxy resin that is solid at 25° C. It was also found that self alignment improves as the mixed ratio of the first epoxy resin that is solid at 25° C. increases, as also supported by the evaluation results for Examples 3 and 9.

When the nixed ratio of the first epoxy resin that is solid at 25° C. was 80 weight parts or more with respect to 100 weight parts of the composite epoxy resin, the fluidity suffered after the first epoxy resin was heated and mixed with the bisphenol F-type epoxy resin used as the second epoxy resin. This made it difficult to form a paste from these resins.

Examples 1, 6, 8, and 10 were compared with Comparative Examples 3 and 4. It was found that the first epoxy resin that is solid at 25° C. needs to have a softening point that is at least 10° C. lower than the melting point of the solder powder, in order to provide self alignment within the acceptable range. This is probably because the softening of the first epoxy resin cannot yield improved self alignment unless the solid firs; epoxy resin does not soften at a temperature below the melting point of the solder powder.

Examples 1, 6, 8, and 10 were compared with Comparative Example 5. It was found that the viscosity of the first epoxy resin at the melting point of the solder powder needs to be limited to provide self alignment within the acceptable range. Specifically, it was found that the viscosity of the first epoxy resin at the melting point of the solder powder needs to be less than 1.5 Pa·s, even when the first epoxy resin that is solid at 25° C. has a softening point that is at least 10° C. smaller than the melting point of the solder powder. On the other hand, self alignment was outside of the acceptable range when the viscosity of the first epoxy resin at the melting point of the solder powder was 2.5 Pa·s. 7his is probably because such a high viscosity of the first epoxy resin at the melting point of the solder powder translates into low fluidity in the composite epoxy resin as a whole at the melting point of the solder powder, and reduces the self alignment produced by melting of the solder powder.

It is not necessarily required that the first epoxy resin that is solid at 25° C. is heated and mixed in advance with the second epoxy resin that is liquid at 25° C. to produce a composite epoxy resin liquid mixture. Specifically, the first epoxy resin can exhibit self alignment even when used in a solid state by being dispersed in the second epoxy resin that is liquid at 25° C. In this case, however, there is a risk of lowering the self alignment improving effect to some extent, because it tends to clog the mask apertures during the screen printing, and increases the time required to completely melt the solid into a liquid. It is therefore more desirable to use the first epoxy resin that is solid at 25° C. in the form of a composite epoxy resin liquid mixture by heating and mixing the first epoxy resin in advance with the second epoxy resin that is liquid at 25° C. In the foregoing Examples and Comparative Examples, a bisphenol F-type epoxy resin is used as the second epoxy resin that is liquid at 25° C. However, it is also possible to use a bisphenol A-type epoxy resin that is liquid at 25° C. The same effect can be obtained in this case, and the combinations of the first epoxy resin and the second epoxy resin are not limited to the foregoing examples in this disclosure.

The self alignment improving effect in the mount step using the solder paste of the present disclosure is exhibited by the softening and the reduced viscosity of the first epoxy resin, and as such the type of solder is not particularly limited. Accordingly, the self alignment obtained with the combinations shown in Table 1 is also obtained in the mount step using the soldering flux of the present disclosure. In this case, the melting point of the solder means the melting point of, for example, the solder bump or solder plating provided for the substrate and the component electrode.

The present disclosure encompasses appropriate combinations of any of the Embodiments and/or Examples described above, and can exhibit effects produced by such combinations of Embodiments and/or Examples.

### INDUSTRIAL APPLICABILITY

The solder paste of the present disclosure has a self alignment improving effect, an effect that cannot be achieved by solder pastes of related art containing a thermosetting resin in a flux component. The present disclosure is therefore useful as a solder paste or a soldering flux for mounting components, and a mounted structure using such a solder paste or a soldering flux.

What is claimed is:

1. A solder paste comprising:
a solder powder;
a composite epoxy resin containing a first epoxy resin that is solid at 25° C., and a second epoxy resin that is liquid at 25° C.; and
a curing agent,
wherein the first epoxy resin has a softening point that is at least 10° C. lower than a melting point of the solder powder, and is contained in a range of 10 weight parts to 75 weight parts with respect to a total 100 weight parts of the composite epoxy resin.

2. The solder paste according claim 1, wherein the composite epoxy resin is a mixed epoxy resin that is liquid at 25° C., and in which the first epoxy resin that is solid at 25° C. is dissolved in the second epoxy resin that is liquid at 25° C.

3. The solder paste according to claim 1, wherein the first epoxy resin has a viscosity of 2 Pa·s or less at the melting point of the solder powder.

4. The solder paste according to claim 1, wherein the solder powder contains Sn and Bi.

5. A soldering flux for soldering an electrode of a substrate and an electrode of a component to be mounted on the substrate to each other, at least one of which is provided with a solder,
the soldering flux comprising:
a composite epoxy resin containing a first epoxy resin that is solid at 25° C., and a second epoxy resin that is liquid at 25° C.; and
a curing agent,
wherein the first epoxy resin has a softening point that is at least 10° C. lower than a melting point of the solder, and is contained in a range of 10 weight parts to 75 weight parts with respect to a total 100 weight parts of the composite epoxy resin.

6. The soldering flux according to claim 5, wherein the composite epoxy resin is a mixed epoxy resin that is liquid at 25° C., and in which the first epoxy resin that is solid at 25° C. is dissolved in the second epoxy resin that is liquid at 25° C.

7. The soldering flux according to claim 5, wherein the first epoxy resin has a viscosity of 2 Pa·s or less at the melting point of the solder.

8. A mounted structure comprising:
a substrate having a plurality of first electrodes;
a component having a second electrode;
a solder that connects between the first electrodes and the second electrode; and
a cured epoxy resin covering at least a part of surroundings of the solder, the cured epoxy resin including a cured composite epoxy resin containing a first epoxy resin that is solid at 25° C., and a second epoxy resin that is liquid at 25° C.,
wherein the first epoxy resin has a softening point that is at least 10° C. lower than the melting point of the solder, and is contained in a range of 10 weight parts to 75 weight parts with respect to the total 100 weight parts of the composite epoxy resin.

9. A mounted structure producing method for producing a mounted structure that includes: a substrate having a plurality of first electrodes; a component having a second electrode; a solder connecting between the first electrodes and the second electrode; and a cured epoxy resin covering at least a part of surroundings of the solder, the method comprising:
providing the solder paste of claim 1 for the plurality of first electrodes provided on the substrate, and/or for the second electrode of the component to be mounted on the substrate;
positioning the plurality of first electrodes provided on the substrate, and the second electrode of the component via the solder paste;
heating the solder paste first to a temperature equal to or greater than the softening point of the first epoxy resin, and then to a temperature equal to or greater than the melting point of the solder powder so as to solder the plurality of first electrodes on the substrate arid the second electrode of the component to each other with the solder paste separated into the solder connecting between the first electrodes and the second electrode, and a cured epoxy resin covering at least a part of surroundings of the solder, and occurring upon curing of the composite epoxy resin containing the first epoxy resin that is solid at 25° C., and the second epoxy resin that is liquid at 25° C.

10. Amounted structure producing method for producing a mounted structure that includes: a substrate having a plurality of first electrodes; a component having a second electrode; a solder connecting between the first electrodes and the second electrode; and a cured epoxy resin covering at least a part of surroundings of the solder,
the method comprising:
providing a solder for the plurality of first electrodes provided on the substrate, and/or for the second electrode of the component to be mounted on the substrate;
providing the soldering flux of claim 5 on the plurality of first electrodes provided on the substrate, and/or on the second electrode of the component to be mounted on the substrate;
positioning the plurality of first electrodes provided on the substrate, and the second electrode of the component via the solder and the soldering flux; and
heating the solder and the soldering flux first to a temperature equal to or greater than the softening point of the first epoxy resin, and then to a temperature equal to or greater than the melting point of the solder so as to solder the plurality of first electrodes on the substrate and the second electrode of the component to each other with the solder connecting between the first electrodes and the second electrode, and with the soldering flux cured into a cured epoxy resin covering at least a part of surroundings of the solder, and occurring upon curing of the composite epoxy resin containing the first epoxy resin that is solid at 25° C., and the second epoxy resin that is liquid at 25° C.

11. The solder paste according to claim 2, wherein the first epoxy resin has a viscosity of 2 Pa·s or less at the melting point of the solder powder.

12. The soldering flux according to claim 6, wherein the first epoxy resin has a viscosity of 2 Pa·s or less at the melting point of the solder.
